(19) United States
(12) Patent Application Publication
(10) Pub. No.: US 2025/0267986 A1
(43) Pub. Date: Aug. 21, 2025

(54) LIGHT EMITTING DEVICE AND LIGHT EMITTING APPARATUS INCLUDING THE SAME

(71) Applicant: SEOUL VIOSYS CO., LTD., Ansan-si (KR)

(72) Inventors: Joon Sub LEE, Ansan-si (KR); Jae Kwon KIM, Ansan-si (KR)

(21) Appl. No.: 19/052,222

(22) Filed: Feb. 12, 2025

Related U.S. Application Data
(60) Provisional application No. 63/555,194, filed on Feb. 19, 2024.

(51) Int. Cl. H10H 20/841; H10H 20/82; H10H 20/857

(52) U.S. Cl. CPC H10H 20/841; H10H 20/82; H10H 20/857

(57) ABSTRACT

A light emitting device including a substrate, light emitting structures spaced apart from each other on the substrate, and a protective layer covering an inclined surface of a side surface of the light emitting device, in which the protective layer includes one or more passivation 5 layers.

### CROSS REFERENCE TO RELATED APPLICATION

This application claims priority from and the benefit of U.S. Provisional Patent Application No. 63/555,194, filed on Feb. 19, 2024, which is hereby incorporated by reference for all purposes as if fully set forth herein.

### BACKGROUND

### Field

Embodiments relate generally to a light emitting device and a light emitting apparatus including the same, and more particularly, to a light emitting device and a light emitting apparatus including a light emitting structure.

### Discussion Of The Background

In recent years, nitride semiconductors have been widely used as a base material for light emitting devices, such as light emitting diodes. Nitride semiconductors can have a wide range of bandgap energies depending on the composition ratio of Group III elements, allowing for the realization of various light wavelengths. By controlling the composition ratio between elements, such as Al, Ga, and In, it is possible to implement light of various wavelengths.

An active layer of a light emitting device may have a multi-quantum well (MQW) structure and an emission wavelength of the light emitting device may be determined by the composition of nitride semiconductors forming well layers of the MQW structure.

Typically, light emitting diodes may be used in the form of a light emitting diode package, in which light emitting diode chips are mounted on a substrate including an interconnection layer and an insulating layer, such as a printed circuit board (PCB), or others.

In general, light emitting diodes are manufactured by sequentially forming semiconductor layers on a substrate and etching the semiconductor layers to create light emitting regions. Then, the substrate is separated into individual light emitting diode chips by a dicing process using a diamond wheel or other cutting methods.

The above information disclosed in this Background section is only for understanding of the background of the inventive concepts, and, therefore, it may contain information that does not constitute prior art.

### SUMMARY

Embodiments provide a light emitting device and a light emitting apparatus that include a light emitting structure capable of simplifying the manufacturing process, effectively protecting the side surface of the light emitting device to prevent delamination, and maximizing the luminous area.

Additional features of the inventive concepts will be set forth in the description which follows, and in part will be apparent from the description, or may be learned by practice of the inventive concepts.

A light emitting device according to one embodiment includes a substrate and light emitting structures spaced apart from each other on the substrate.

In one embodiment, an inclined surface may be formed on a side surface of the light emitting device.

In one embodiment, the light emitting device may include one or more passivation layers covering the inclined surface.

In one embodiment, the light emitting structures may include a first conductivity type semiconductor layer having an upper surface partially exposed, an active layer disposed on the first conductivity type semiconductor layer, and a second conductivity type semiconductor layer disposed on the active layer.

In one embodiment, the inclined surface may extend from the exposed upper surface of the first conductivity type semiconductor layer to the substrate.

In one embodiment, the light emitting device may include: a first passivation layer disposed on the light emitting structure and covering the inclined surface; a second metal layer disposed on the first passivation layer and electrically connected to the second conductivity type semiconductor layer; a second passivation layer disposed on the second metal layer and covering the first passivation layer in a region of the inclined surface; a first metal layer disposed on the second passivation layer and electrically connected to the first conductivity type semiconductor layer; and a third passivation layer disposed on the first metal layer and covering the second passivation layer in the region of the inclined surface.

In one embodiment, the light emitting device may include: a first passivation layer disposed on the light emitting structures; a second metal layer disposed on the first passivation layer and electrically connected to the second conductivity type semiconductor layer; a second passivation layer disposed on the second metal layer and covering the inclined surface; a first metal layer disposed on the second passivation layer and electrically connected to the first conductivity type semiconductor layer; and a third passivation layer disposed on the first metal layer and covering the second passivation layer in a region of the inclined surface.

In one embodiment, the light emitting device may include: a first passivation layer disposed on the light emitting structures; a second metal layer disposed on the first passivation layer and electrically connected to the second conductivity type semiconductor layer; a second passivation layer disposed on the second metal layer; a first metal layer disposed on the second passivation layer and electrically connected to the first conductivity type semiconductor layer; and a third passivation layer disposed on the first metal layer and covering the inclined surface.

In one embodiment, a thickness of the passivation layers in the region of the inclined surface may gradually decrease toward the substrate from the light emitting structure.

In one embodiment, a vertical depth from a boundary between the substrate and the light emitting structure to the lowermost end of the inclined surface may be greater than or equal to 0.4% of a thickness of the substrate.

In one embodiment, a vertical depth from a boundary between the substrate and the light emitting structure to the lowermost end of the inclined surface may range from 0.1 μm to 50 μm.

In one embodiment, an angle defined between the inclined surface and a vertical plane may be less than or equal to 10°.

In one embodiment, an inclination of the inclined surface with respect to the vertical plane is varied at a boundary between the substrate and the light emitting structure.

In one embodiment, at the uppermost end of the inclined surface, a distance between the inclined surface and a vertical plane may be less than or equal to 20 μm.

In one embodiment, at a boundary between the substrate and the light emitting structure, a distance between the inclined surface and a vertical plane may be less than or equal to 10 μm.

In one embodiment, the inclined surface may overlap a roughness region on a side surface of the substrate.

In one embodiment, the passivation layers may form a curved surface at an upper end of the inclined surface.

In one embodiment, at least one of the second passivation layer or the third passivation layer may be a DBR layer.

In one embodiment, at least a partial region of the DBR layer may be a thickness variable region where a vertical thickness varies.

A light emitting device according to another embodiment includes: a substrate; a first conductivity type semiconductor layer disposed on the substrate and having an upper surface partially exposed; and a mesa disposed on the first conductivity type semiconductor layer and including an active layer and a second conductivity type semiconductor layer.

In one embodiment, an inclined surface may be formed on a side surface of the light emitting device.

In one embodiment, the light emitting device may include one or more passivation layers covering the inclined surface.

In one embodiment, an inclination of the inclined surface with respect to the vertical plane may be varied at a boundary between the substrate and the first conductivity type semiconductor layer.

In one embodiment, an inclination of the inclined surface with respect to the vertical plane on the first conductivity type semiconductor layer may be greater than an inclination of the inclined surface with respect to the vertical plane on the substrate.

A light emitting apparatus may include the light emitting device described above.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the inventive concepts and are incorporated in and constitute a part of this specification, illustrate embodiments, and together with the description serve to explain the inventive concepts.

FIG. 1 is a plan view of a light emitting device according to an embodiment.

FIG. 2 is a cross-sectional view of a light emitting device according to a first embodiment.

FIG. 3 is a cross-sectional view of a light emitting device according to a second embodiment.

FIG. 4 is a cross-sectional view of a light emitting device according to a third embodiment.

FIG. 5 is an enlarged view of Region E of FIG. 4 according to an embodiment.

FIG. 6 is an enlarged view of Region E of FIG. 4 according to another embodiment.

FIG. 7 is an enlarged view of Region K of FIG. 2.

FIG. 8 is a view of a curved shape of a passivation layer covering an inclined surface.

FIG. 9A and FIG. 9B are views of an inclined surface formed on a side surface of a light emitting device.

### DETAILED DESCRIPTION

In the following description, for the purposes of explanation, numerous specific details are set forth in order to provide a thorough understanding of various embodiments or implementations. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing.

In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Embodiments provide a light emitting device 100 including a substrate 110 and light emitting structures 120 spaced apart from each other on the substrate 110. Hereinafter, embodiments will be described in more detail with reference to the accompanying drawings.

The substrate 110 is a growth substrate for growing the light emitting structure 120 described below, and may be selected from any substrate that allows growth of semiconductor layers thereon without limitation. For example, the substrate 110 may include a heterogeneous substrate, such as a sapphire substrate, a silicon substrate, a silicon carbide substrate, or a spinel substrate, and may also include a homogeneous substrate, such as a gallium nitride substrate, an aluminum nitride substrate, or others.

At least one light emitting structure 120 may be disposed on the substrate 110. The light emitting structure 120 may include semiconductor layers grown on the substrate 110, and may include a first conductivity type semiconductor layer 122, an active layer 124 disposed on the first conductivity type semiconductor layer 122, and a second conductivity type semiconductor layer 126 disposed on the active layer 124. In some embodiments, a plurality of light emitting structures 120 may be disposed on the substrate 110.

The first conductivity type semiconductor layer 122 may be a semiconductor layer grown on one surface of the substrate 110, and a buffer layer may be further formed between the first conductivity type semiconductor layer 122 and the substrate 110. The buffer layer may include a nitride semiconductor, such as GaN, and may be grown by MOCVD. The buffer layer can improve crystallinity of the semiconductor layers grown on the growth substrate in a subsequent process and can also act as a seed layer for nitride semiconductor layers to be grown on a heterogeneous substrate.

The first conductivity type semiconductor layer 122 may include a nitride semiconductor, such as (Al, Ga, In) N, and may be grown on the growth substrate 110 by various methods, such as MOCVD, MBE, HVPE, or others. In addition, the first conductivity type semiconductor layer 122 may be doped with at least one type of n-type dopant, such as Si, C, Ge, Sn, Te, Pb, or others, without being limited thereto. Alternatively, the first conductivity type semiconductor layer 122 may be doped with a p-type dopant to become an opposite conductivity type.

The active layer 124 is a light emitting layer disposed on the first conductivity type semiconductor layer 122 and may have a multi-quantum well (MQW) structure.

The active layer 123 may include a nitride semiconductor, such as (Al, Ga, In) N, and may be grown on the first conductivity type semiconductor layer 122 by various methods, such as MOCVD, MBE, or HVPE.

In addition, the active layer 124 may include a quantum-well (QW) structure including at least two barrier layers and at least one well layer. Alternatively, the active layer 124 may include a multi-quantum well (MQW) structure including a plurality of barrier layers and a plurality of well layers.

The wavelength of light emitted from the active layer 124 may be adjusted by controlling the composition of a nitride semiconductor layer in the well layer. The well layer may include a nitride semiconductor containing indium (In).

The well layer is interposed between the barrier layers and has a narrower energy bandgap than the barrier layer.

The well layer may include or be formed of InₓGa₍₁₋ₓ₎N (0<x<1) and the composition ratio (x) of In may be controlled according to the wavelength of light emitted from the active layer.

The barrier layers and the well layers are stacked one above another to alternate with each other, preferably at least twice. A barrier layer and a well layer adjacent thereto may constitute a pair.

The second conductivity type semiconductor layer 126 may be a semiconductor layer disposed on the active layer 124.

The second conductivity type semiconductor layer 126 may include a nitride semiconductor, such as (Al, Ga, In) N, and may be grown by various methods, such as MOCVD, MBE, or HVPE.

The second conductivity type semiconductor layer 126 may be doped to have a conductivity type opposite to the conductivity type of the first conductivity type semiconductor layer 122. For example, the second conductivity type semiconductor layer 126 may be doped with p-type dopants, such as Mg.

The second conductivity type semiconductor layer 126 may be formed in a monolayer structure having a composition, such as p-GaN, and may further include an AlGaN layer therein, without being limited thereto.

An upper surface of the first conductivity type semiconductor layer 122 may be partially exposed by etching the active layer 124 and the second conductivity type semiconductor layer 126.

Specifically, the upper surface of the first conductivity type semiconductor layer 122 may be partially exposed and a mesa may be formed by etching the active layer 124 and the second conductivity type semiconductor layer 126, or by partially etching the active layer 124, the second conductivity type semiconductor layer 126, and the first conductivity type semiconductor layer 122.

The mesa has a protruding structure formed by patterning the active layer 124 and the second conductivity type semiconductor layer 126 and may be disposed on the first conductivity type semiconductor layer 122.

The mesa includes the active layer 124 and the second conductivity type semiconductor layer 126, and may further include a region of the first conductivity type semiconductor layer 122.

The mesa may have various shapes and may include, for example, a palm portion and a finger portion, or may include one or more grooves having substantially a rectangular shape in plan view.

The first conductivity type semiconductor layer 122 is exposed around the mesa and the mesa may have an inclined side surface. The inclination profile of the side surface of the mesa can improve extraction efficiency of light generated in the active layer 124.

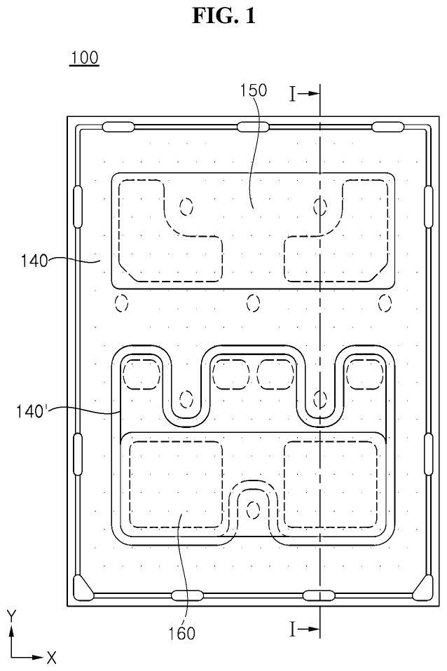

The light emitting device 100 may be divided through a dicing process and may be configured in the form as shown in FIG. 1.

More particularly, the substrate 110 on which a plurality of light emitting structures 120 are disposed is divided into individual light emitting devices 100 through the dicing process. Here, a V-shaped groove may be formed along a dicing line and may be formed along the circumference of the light emitting structure 120 that is divided to form a single light emitting device 100. Accordingly, an inclined surface G may be formed on an outer side surface of the light emitting device 100

For the light emitting device 100 including a plurality of light emitting cells, the grooves may be formed between the plurality of light emitting cells.

As the light emitting structure 120 forms a mesa structure, the inclined surface G may be formed along the circumference of the mesa.

The inclined surface G may extend from the exposed upper surface of the first conductivity type semiconductor layer 122 to a side surface of the substrate 110.

The lowermost point Q of the inclined surface G may be disposed on the substrate 110, and a horizontal distance W in a region of the inclined surface G at the uppermost end of the inclined surface G (that is, on the upper surface of the first conductivity type semiconductor layer 122) and a vertical depth D (that is, from the upper surface of the first conductivity type semiconductor layer 122 to the lowermost point Q) may be set in various ways.

The light emitting device constructed according to inventive concepts secures a large luminous area on the substrate 110 by forming the inclined surface G.

Here, the light emitting device 100 may include a protective layer, which may include one or more passivation layers P1, P2, P3, covering the inclined surface G.

Since the inclined surface G is covered with the one or more passivation layers P1, P2, P3, the inclined surface G is protected from an external environment instead of being exposed thereto.

After the dicing process, an inner circumferential surface of the groove forms a side surface including the inclined surface G of the individual light emitting device 100 and the inclined surface G is protected by the passivation layers P1, P2, P3, thereby effectively preventing delamination of the light emitting device 100.

In other words, since the inclined surface G extends to a certain depth of the side surface of the substrate 110, the passivation layers P1, P2, P3 covering the inclined surface G can cover not only the side surface of the first conductivity type semiconductor layer 122 of the light emitting device 100 but also the side surface of the substrate 110. As a result, since a boundary B between the first conductivity type semiconductor layer 122 and the substrate 110 is covered by the passivation layers P1, P2, P3, the light emitting device 100 can prevent delamination of the first conductivity type semiconductor layer 122 from the substrate 110.

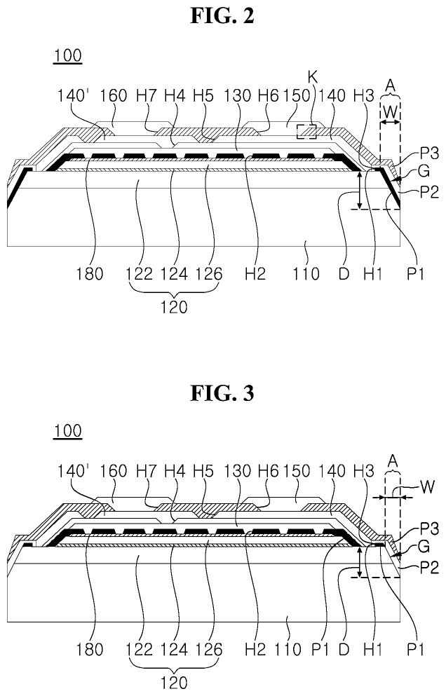

In a region of the inclined surface G (Region A in FIG. 2 to FIG. 4), the thickness of the passivation layers P1, P2, P3 covering the inclined surface G may gradually decrease in a direction from the first conductivity type semiconductor layer 122 to the substrate 110.

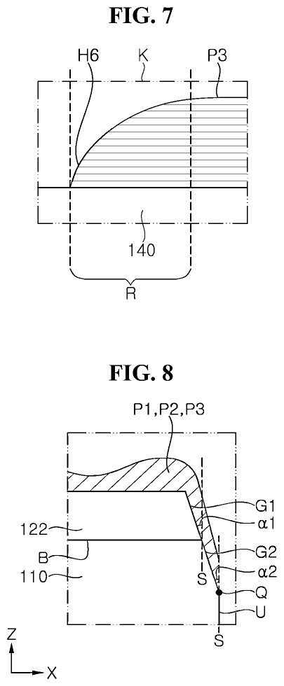

Next, referring to FIG. 8, the passivation layers P1, P2, P3 cover the inclined surface G along the shape of the inclined surface G and thus may form a curved surface at an upper end of the inclined surface G (where the upper surface of the first conductivity type semiconductor layer 122 meets the inclined surface G). At the upper end of the inclined surface G (where the upper surface of the first conductivity type semiconductor layer 122 meets the inclined surface G), the passivation layers P1, P2, P3 may be formed thicker than in other regions, thereby forming a protruding curved surface. Thus, it is possible to prevent an imbalance in a current flow due to damage at a corner of the first conductivity type semiconductor layer 122.

A vertical depth D2 of the inclined surface G from the boundary B between the substrate 110 and the light emitting structure 120 to the lowermost point Q of the inclined surface G may be 0.4% or more of the thickness of the substrate 110. In some embodiments, a horizontal distance between the boundary B and a vertical line passing through the lowermost point Q of the inclined surface G may be 10 μm or less.

Alternatively, the vertical depth D2 from the boundary B between the substrate 110 and the light emitting structure 120 to the lowermost point Q of the inclined surface G may range from 0.1 μm to 50 μm. Since an excessive vertical depth D2 can cause reduction in luminous area while a shallow vertical depth D2 can cause the passivation layers P1, P2, P3 to insufficiently cover the inclined surface G, it is desirable that the vertical depth D2 range from 0.1 μm to 50 μm.

Referring to FIG. 8, angles α1, α2 defined between inclined surfaces G1, G2 and a vertical plane S may have various values. For example, the angle α1, α2 defined between the inclined surfaces G1, G2 and the vertical plane S may be less than or equal to 10°. Here, G1 denotes a first inclined surface G1 of the first conductivity type semiconductor layer 122 and α1 denotes a first angle α1 defined between the first inclined surface G1 and the vertical plane S. G2 denotes a second inclined surface G2 of the substrate 110 and α2 denotes a second angle α2 defined between the second inclined surface G2 and the vertical plane S.

Referring to FIG. 8, the first angle α1 and the second angle α2 may have various values. For example, the second angle α2 defined between the second inclined surface G2 and the vertical plane S may be 10° or less.

Although the inclined surface G is exemplarily shown as a flat surface in the drawings, however, the inventive concepts are not limited thereto. In some embodiments, the inclined surface G may have a roughness structure in various shapes.

The light emitting device 100 may have inclined surfaces G at opposite sides thereof to face each other, and angles α defined between the inclined surfaces G facing each other and the vertical plane S may be different from each other. That is, the inclined surfaces G facing each other may form an asymmetrical structure with respect to the vertical plane S.

The angle α defined between the inclined surface G and the vertical plane S may include at least one angle change point at which the angle α is varied.

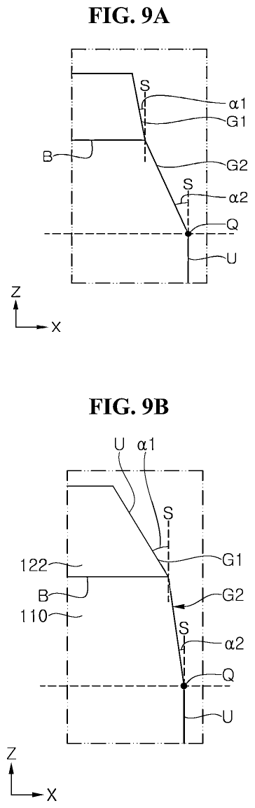

The angle change point may be a point at which properties of a layer constituting the inclined surface G are changed, and may include, for example, the boundary B between the first conductivity type semiconductor layer 122 and the substrate 110. That is, the inclination of each of the inclined surfaces G1, G2 may be variable at the boundary B between the substrate 110 and the light emitting structure 120. In other words, the inclinations of the inclined surfaces G1, G2 with respect to the vertical plane S may be variable at the boundary B between the substrate 110 and the light emitting structure 120. More particularly, the first angle α1 may be different from the second angle α2. For example, as shown in FIG. 9A, the inclined surface G may include a first inclined surface G1 formed in a zone of the first conductivity type semiconductor layer 122, and the first inclined surface G1 may form the first angle α1 with respect to the vertical plane S. In addition, the inclined surface G may include a second inclined surface G2 formed in a zone of the substrate 110 and the second inclined surface G2 may form the second angle α2 with respect to the vertical plane S. The first angle α1 and the second angle α2 may have different values. The second angle α2 may be greater than the first angle α1.

The first inclined surface G1 and the second inclined surface G2 may have different surface lengths. The second inclined surface G2 may have a greater surface length than the first inclined surface G1. Thus, the passivation layers P1, P2, P3 may sufficiently cover the side surface of the substrate 110.

As another example, as shown in FIG. 9B, the vertical plane S and the first inclined surface G1 may define the first angle α1 therebetween and the substrate 110 and the second inclined surface G2 may define the second angle α1 therebetween. According to the illustrated embodiment, the second angle α2 may be less than the first angle α1.

In FIG. 9A and FIG. 9B, the passivation layers P1, P2, P3 are omitted to clearly show the shape of the inclined surfaces G1, G2.

On the other hand, at the uppermost end of the inclined surface G (that is, on the upper surface of the first conductivity type semiconductor layer 122), Region A of the inclined surface G may have a horizontal distance W of 20 μm or less.

At the uppermost end of the inclined surface G, the horizontal distances W of Region A of the inclined surfaces G with respect to the two inclined surfaces G at both sides of the mesa may be different from each other.

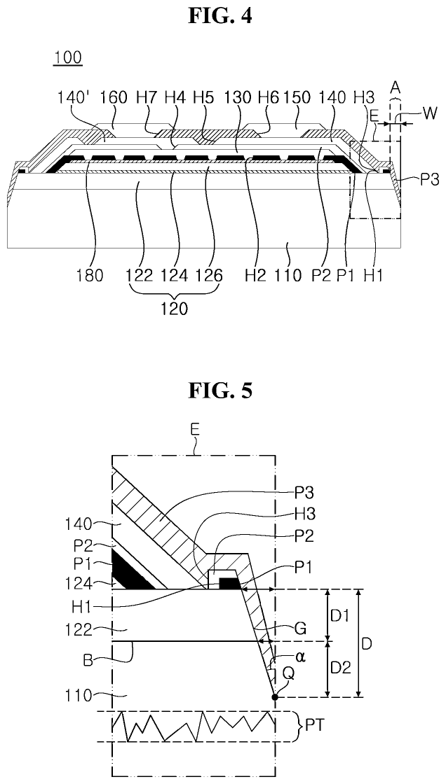

According to an embodiment illustrated in FIG. 5, the substrate 110 may be provided on a side surface thereof with a roughness region PT. For example, the lowermost point Q of the inclined surface G may be placed above a roughness region PT on the side surface of the substrate 110 and the inclined surface G may overlap the roughness region PT in a vertical direction. The inclined surface G may not overlap the roughness region PT in a horizontal direction. Accordingly, light generated in the active layer 124 may be diffused in the roughness region PT to be emitted outside.

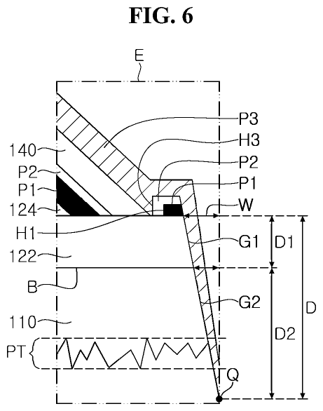

According to another embodiment illustrated in FIG. 6, the lowermost point Q of the inclined surface G is placed below the roughness region PT on the side surface of the substrate 110. In this case, the inclined surface G may overlap the roughness region PT in the vertical direction and in the horizontal direction. As the passivation layers P1, P2, P3 cover the roughness region PT, the passivation layers P1, P2, P3 can be more firmly attached to the substrate 110 through an increased surface area of the roughness region PT.

The inclined surface G may be covered by at least one passivation layer P1, P2, P3. As a first embodiment, the inclined surface G may be covered by the first to third passivation layers P1, P2, P3, that is, three passivation layers P1, P2, P3. Alternatively, as a second embodiment, the inclined surface G may be covered by the second and third passivation layers P2, P3, that is, two passivation layers P2, P3. Alternatively, as a third embodiment, the inclined surface G may be covered by the third passivation layer P3, that is, a single passivation layer P3.

Hereinafter, the light emitting devices 100 according to the first to third embodiments will be described in detail with reference to FIGS. 2 to 4.

Referring to FIG. 2, the light emitting device 100 according to the first embodiment includes: a first passivation layer P1 disposed on the light emitting structure 120 and covering the inclined surface G; a second metal layer 130 disposed on the first passivation layer P1 and electrically connected to the second conductivity type semiconductor layer 126; a second passivation layer P2 disposed on the second metal layer 130 and covering the first passivation layer P1 in a region of the inclined surface G; a first metal layer 140 disposed on the second passivation layer P2 and electrically connected to the first conductivity type semiconductor layer 122; and a third passivation layer P3 disposed on the first metal layer 140 and covering the second passivation layer P2 on the inclined surface G.

The first passivation layer P1 may be disposed on the light emitting structure 120 described above and may cover a first light emitting structure 120 and the inclined surface G. The first passivation layer P1 may include an insulating layer and may act as a current blocking layer (CBL). More particularly, the first passivation layer P1 may be an insulating layer disposed on the mesa and contacting the second conductivity type semiconductor layer 126. The first passivation layer P1 may include SiO₂.

In addition, the first passivation layer PI may cover the entirety of the inclined surface G and may include at least one first opening H1 partially exposing the first conductivity type semiconductor layer 122 and at least one second opening H2 partially exposing the second conductivity type semiconductor layer 126.

The first opening H1 may be a hole disposed at an edge (mesa edge) of the light emitting structure 120 and partially exposing the upper surface of the first conductivity type semiconductor layer 122, and the second opening H2 may be a hole disposed on the upper surface of the second conductivity type semiconductor layer 126 and partially exposing the second conductivity type semiconductor layer 126. The first opening H1 and the second opening H2 may be provided singularly or in plural.

The light emitting device 100 may further include an ohmic layer 180 disposed between the first passivation layer P1 and the second conductivity type semiconductor layer 126.

The ohmic layer 180 may include a transparent oxide layer, such as an indium tin oxide (ITO) or ZnO layer, which is disposed on the second conductivity type semiconductor layer 126 and contacts the second conductivity type semiconductor layer 126.

The ohmic layer 180 is optionally formed and provides an advantage of improving light extraction efficiency by refracting and diffusing light, which is generated in the active layer 124 and reaches the ohmic layer 180, at an interface between the ohmic layer 180 and the second conductivity type semiconductor layer 126.

The ohmic layer 180 may be exposed through the second opening H2 of the first passivation layer P1.

The second metal layer 130 is disposed on the first passivation layer P1 to be electrically connected to the second conductivity type semiconductor layer 126, and may be formed in various configurations.

Referring to FIG. 2, the second metal layer 130 may be a layer disposed on the second conductivity type semiconductor layer 126. That is, the second metal layer 130 may be a metal layer disposed on the mesa.

The second metal layer 130 may be electrically connected to the second conductivity type semiconductor layer 126 through the second opening H2 of the first passivation layer P1.

The second passivation layer P2 may be disposed on the second metal layer 130 and may cover the first passivation layer P1 on the inclined surface G.

In addition, the second passivation layer P2 may be disposed on the first passivation layer P1 to cover the inclined surface G and may include at least one third opening H3 partially exposing the first conductivity type semiconductor layer 122 and at least one fourth opening H4 partially exposing the second metal layer 130.

The third opening H3 may be a hole disposed at an edge (mesa edge) of the light emitting structure 120 and partially exposing the upper surface of the first conductivity type semiconductor layer 122, and may be formed in a region corresponding to the first opening H1 of the first passivation layers P1.

The fourth opening H4 may be a hole disposed on the upper surface of the second metal layer 130 and partially exposing the second metal layer 130.

The second passivation layer P2 may have a SiO₂ monolayer structure or multilayer structure that includes a plurality of layers having different indices of refraction. As an example of the multilayer structure, the second passivation layer P2 may include a distributed Bragg reflective layer (DBR layer) in which high refractivity layers and low refractivity layers are alternately stacked one above another. By way of example, the second passivation layer P2 may include an insulating reflective layer with high reflectivity, which is formed by stacking layers, such as SiO₂/TiO₂ layers or SiO₂/Nb₂O₅ layers.

Next, referring to FIG. 2, the first metal layer 140 may be disposed on the second passivation layer P2 and may be electrically connected to the first conductivity type semiconductor layer 122.

The first metal layer 140 may be electrically connected to the first conductivity type semiconductor layer 122 at the edge of the light emitting structure 120, that is, at the mesa edge, through the third opening H3 of the second passivation layer P2.

In addition, the first metal layer 140 may include a fifth opening H5 disposed in an upper region of the second passivation layer P2 and including the fourth opening H4 of the second conductivity type semiconductor layer 126 to partially expose the second passivation layer P2.

The fifth opening H5 may be placed in an upper region of the mesa and may partially expose the first metal layer 130 through the fourth opening H4.

An interconnection layer 140′ may be placed on the second passivation layer P2 inside the second opening H5.

The interconnection layer 140′ may be spaced apart from the first metal layer 140 inside the second opening H5 and may be electrically connected to the second metal layer 130 exposed through the fourth opening H2 of the second passivation layer P2.

The interconnection layer 140′ may be a metal layer formed together with the second metal layer 140.

The third passivation layer P3 may be an insulating layer disposed on the first metal layer 140 and covering the second passivation layer P2 in Region A of the inclined surface G.

In addition, the third passivation layer P3 may be disposed on the second passivation layer P2 to cover the inclined surface G and may include a sixth opening H6 partially exposing the first metal layer 140 above the second conductivity type semiconductor layer 126 (that is, in a region above the mesa), and a seventh opening H7 partially exposing the interconnection layer 140′.

The sixth opening H6 may be a hole disposed on an upper surface of the first metal layer 140 and partially exposing the first metal layer 140, and the seventh opening H7 may be a hole partially exposing the interconnection layer 140′.

The first metal layer 140 and the interconnection layer 140′ may be insulated from each other by the third passivation layer P3.

The third passivation layer P3 may be a SiO₂ monolayer or multilayer structure. As an example of the multilayer structure, the third passivation layer P3 may include a distributed Bragg reflective layer (DBR layer) in which high refractivity layers and low refractivity layers are alternately stacked one above another. By way of example, the third passivation layer P3 may be an insulating reflective layer with high reflectivity, which is formed by stacking layers, such as SiO₂/TiO₂ layers or SiO₂/Nb₂O₅ layers.

FIG. 7 is an enlarged view of Region K shown in FIG. 2, showing a region in which the sixth opening H6 is formed when the third passivation layer P3 includes a DBR layer. Referring to FIG. 7, as the sixth opening H6 exposing the first metal layer 130 is formed in the third passivation layer P3, the DBR layer may include a thickness variable region R in at least a partial region thereof, in which the thickness of the DBR layer varies in the vertical direction.

In the thickness variable region R, the number of layers constituting the DBR layer may be different from the number of layers constituting the DBR layer in other regions, and the number of layers constituting the DBR layer and the thickness of the DBR layer may be gradually increased in a direction away from the sixth opening H6.

The thickness variable region R may be formed near the openings H6, H7 and may be formed near the openings H3, H4 when not only the third passivation layer P3 but also the second passivation layer P2 includes the DBR layer.

In a region above the mesa, a first electrode pad 150 and a second electrode pad 160 may be placed on the third passivation layer P3.

The first electrode pad 150 may be electrically connected to the first metal layer 130 through the sixth opening H6 of the third passivation layer P3, and the second electrode pad 160 may be electrically connected to the interconnection layer 140′ through the seventh opening H7 of the third passivation layer P3.

In the light emitting device 100 according to the first embodiment described above, the first to third passivation layers P1, P2, P3 may be stacked in Region A in which the inclined surface G is formed. Depending on reflectivity and transmittance of each layer constituting the first to third passivation layers and the shape of Region A of the inclined surface G, light extraction efficiency of the light emitting device can be improved.

In the light emitting device 100 according to the second embodiment shown in FIG. 3, the second and third passivation layers P2, P3 may be sequentially stacked on the inclined surface G in Region A where the inclined surface G is formed, unlike in the first embodiment. The light emitting device 100 according to the second embodiment may have a similar configuration to the light emitting device according to the first embodiment except that the inclined surface G is covered by two passivation layers P2, P3, and thus, repeated descriptions will be omitted.

Specifically, the light emitting device 100 according to the second embodiment includes: a first passivation layer P1 disposed on the light emitting structure 120 and covering the inclined surface G; a second metal layer 130 disposed on the first passivation layer P1 and electrically connected to the second conductivity type semiconductor layer 126; and a second passivation layer P2 disposed on the second metal layer 130 and covering the first passivation layer P2 in a region of the inclined surface G; a first metal layer 140 disposed on the second passivation layer P2 and electrically connected to the first conductivity type semiconductor layer 122; and a third passivation layer P3 disposed on the first metal layer 140 and covering the second passivation layer P3 in the region of the inclined surface G.

Unlike in the first embodiment, the first passivation layer P1 in the second embodiment may be formed so as not to cover the inclined surface G, such that the inclined surface G can be exposed. This structure may be realized by forming the inclined surface G after forming the first passivation layer P1. On the other hand, in the first embodiment, the first passivation layer P1 may cover the inclined surface G by forming a V-shaped groove before the first passivation layer P1 is formed.

In the light emitting device 100 according to the third embodiment shown in FIG. 4, the third passivation layer P3 may be stacked in Region A in which the inclined surface G is formed, unlike in the first and second embodiments. The light emitting device 100 according to the third embodiment may have a similar configuration to the light emitting devices according to the first and second embodiments except that the inclined surface G is covered by one passivation layer P3, and thus, repeated descriptions will be omitted.

Unlike in the first and second embodiments, the first and second passivation layers P1, P2 are configured so as not to cover the inclined surface G. This structure can be realized by performing a process of forming the groove after forming the first and second passivation layers P1, P2.

Each of the light emitting structures 120 may be divided into individual light emitting devices 100 by a dicing process.

As the dicing process is carried out along the groove, the inclined surface G formed on the inner circumferential surface of the groove may partially constitute the side surface of the light emitting device 100.

That is, the inclined surface G may be formed on the side surface of the light emitting device 100 and may be covered by at least one passivation layer P1, P2, P3.

The side surface of the light emitting device 100 may include the inclined surfaces G1, G2 caused by the groove and a cut surface U formed by the dicing process. As described above, the inclined surfaces G1, G2 may be variable at the boundary B between the first conductivity type semiconductor layer 122 and the substrate 110.

The cut surface U may form a vertical plane S or may form an inclined surface with respect to the vertical plane S. An angle defined between the cut surface U and the vertical plane S may be different from the angle defined between the inclined surfaces G1, G2 and the vertical plane S.

The light emitting device 100 is a light emitting diode chip and may be applied to various light emitting apparatuses, such as lighting, displays, or others, through a packaging process.

Embodiments provide a light emitting device and a light emitting apparatus that include a light emitting structure capable of simplifying the manufacturing process, effectively protecting the side surface of the light emitting device to prevent delamination, and maximizing the luminous area.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting device comprising:
a substrate;
light emitting structures spaced apart from each other on the substrate; and
a protective layer covering an inclined surface formed on a side surface of the light emitting device,
wherein the protective layer comprises one or more passivation layers.

2. The light emitting device according to claim 1, wherein the light emitting structures include a first conductivity type semiconductor layer having an upper surface partially exposed, an active layer disposed on the first conductivity type semiconductor layer, and a second conductivity type semiconductor layer disposed on the active layer, and
wherein the inclined surface extends from the exposed upper surface of the first conductivity type semiconductor layer to the substrate.

3. The light emitting device according to claim 2, wherein:
the protective layer comprises:
a first passivation layer disposed on the light emitting structure and covering the inclined surface;
a second passivation layer disposed on the first passivation layer and covering the first passivation layer in a region of the inclined surface; and
a third passivation layer disposed on the second passivation layer and covering
the second passivation layer in the region of the inclined surface; and
the light emitting device further includes:
a first metal layer disposed on the second passivation layer and electrically connected to the first conductivity type semiconductor layer; and
a second metal layer disposed on the first passivation layer and electrically connected to the second conductivity type semiconductor layer.

4. The light emitting device according to claim 2, wherein:
the protective layer comprises:
a first passivation layer disposed on the light emitting structures;
a second passivation layer disposed on the first passivation layer and covering the inclined surface; and
a third passivation layer disposed on the second passivation layer and covering the second passivation layer in a region of the inclined surface; and
the light emitting device further includes:
a first metal layer disposed on the second passivation layer and electrically connected to the first conductivity type semiconductor layer; and 10
a second metal layer disposed on the first passivation layer and electrically connected to the second conductivity type semiconductor layer.

5. The light emitting device according to claim 2, wherein:
the protective layer comprises:
a first passivation layer disposed on the light emitting structures;
a second passivation layer disposed on the first passivation layer;
a third passivation layer disposed on the second passivation layer and covering the inclined surface; and
the light emitting device further includes:
a first metal layer disposed on the second passivation layer and electrically connected to the first conductivity type semiconductor layer; and
a second metal layer disposed on the first passivation layer and electrically connected to the second conductivity type semiconductor layer.

6. The light emitting device according to claim 3, wherein a thickness of the protective layer in the region of the inclined surface gradually decreases toward the substrate from the light emitting structure.

7. The light emitting device according to claim 1, wherein a vertical depth from a boundary between the substrate and the light emitting structure to the lowermost end of the inclined surface is greater than or equal to 0.4% of a thickness of the substrate.

8. The light emitting device according to claim 1, wherein a vertical depth from a boundary between the substrate and the light emitting structure to the lowermost end of the inclined surface ranges from 0.1 μm to 50 μm.

9. The light emitting device according to claim 1, wherein an angle defined between the inclined surface and a vertical plane is less than or equal to 10°.

10. The light emitting device according to claim 1, wherein an inclination of the inclined surface with respect to a vertical plane is varied at a boundary between the substrate and the light emitting structure.

11. The light emitting device according to claim 1, wherein, a horizontal distance between the uppermost end of the inclined surface and a vertical line passing through a lowermost point of the inclined surface plane is less than or equal to 20 μm.

12. The light emitting device according to claim 1, wherein, a horizontal distance between a boundary between the substrate and the light emitting structure and vertical line passing through a lowermost point of the inclined surface is less than or equal to 10 μm

13. The light emitting device according to claim 1, wherein the inclined surface overlaps a roughness region on a side surface of the substrate.

14. The light emitting device according to claim 1, wherein the protective layer forms a curved surface at an upper end of the inclined surface.

15. The light emitting device according to claim 3, wherein at least one of the second passivation layer or the third passivation layer comprises a DBR layer.

16. The light emitting device according to claim 3, wherein at least a partial region of the DBR layer is a thickness variable region where a vertical thickness varies.

17. A light emitting device comprising:
a substrate;
a first conductivity type semiconductor layer disposed on the substrate and having an upper surface partially exposed; and
a mesa disposed on the first conductivity type semiconductor layer and including an active layer and a second conductivity type semiconductor layer,
wherein an inclined surface is formed on a side surface of the light emitting device, and
wherein the light emitting device comprises one or more passivation layers covering the inclined surface.

18. The light emitting device according to claim 17, wherein an inclination of the inclined surface with respect to a vertical plane is varied at a boundary between the substrate and the first conductivity type semiconductor layer.

19. The light emitting device according to claim 18, wherein an inclination of the inclined surface with respect to the vertical plane on the first conductivity type semiconductor layer is greater than an inclination of the inclined surface with respect to the vertical plane on the substrate.

20. A light emitting apparatus comprising the light emitting device according to claim 1.
